(19) United States
(12) Patent Application Publication
(10) Pub. No.: US 2005/0284373 A1
(43) Pub. Date: Dec. 29, 2005

(54) Apparatus for manufacturing a luminescent device using a buffer cassette

(75) Inventor: Sung-Jae Jung, Kyongsangbuk-do (KR)

Correspondence Address: BIRCH STEWART KOLASCH & BIRCH, PO BOX 747, FALLS CHURCH, VA, 22040-0747, US

(73) Assignee: LG Electronics Inc., Seoul (KR)

(21) Appl. No.: 11/159,325

(22) Filed: Jun. 23, 2005

(30) Foreign Application Priority Data
Jun. 25, 2004 (KR) 2004-48093
Jun. 25, 2004 (KR) 2004-48106
Jun. 25, 2004 (KR) 2004-48108

(51) Int. Cl. C23C 16/00

(52) U.S. Cl. 118/719

(57) ABSTRACT

The present invention relates to an apparatus for manufacturing a luminescent device using a buffer cassette which stores substrates. An apparatus of manufacturing the luminescent device according to first embodiment of the present invention includes a depositing section, a sealing section, and a buffer cassette. The depositing section deposits a film on each of substrates. The sealing section receives the deposited substrates from the depositing section, and seals the received substrates. The buffer cassette stores the substrates transferred from the depositing section, and is located between the depositing section and the sealing section. The apparatus may perform depositing process or sealing process to substrates by using a buffer cassette in case that a part thereof is broken down. Therefore, the manufacture yield of the luminescent device is enhanced.

### CROSS-REFERENCE TO RELATED APPLICATIONS

This application claims priority from Korean Patent Application Nos. 2004-48093, 2004-48106 and 2004-48108 filed on Jun. 25, 2004, the contents of which are incorporated herein by reference in their entirety.

### BACKGROUND OF THE INVENTION

1. Field of the Invention

The present invention relates to an apparatus for manufacturing a luminescent device. In particular, the present invention relates to an apparatus for manufacturing a luminescent device using a buffer cassette which stores substrates.

2. Description of the Related Art

A luminescent device emits light having predetermined wavelength.

To manufacture the luminescent device, deposition process and sealing process should be performed.

Thus, a conventional apparatus for manufacturing the luminescent device includes a depositing apparatus for performing the deposition process and a sealing apparatus for performing the sealing process.

Here, the depositing apparatus and the sealing apparatus are combined in one body in order to maintain vacuum atmosphere.

Hence, in case that the deposition apparatus or the sealing apparatus is broken down, the deposition apparatus and the sealing apparatus stop functioning together. As a result, the manufacture yield of the luminescent device is not good.

### SUMMARY OF THE INVENTION

It is a feature of the present invention to provide an apparatus for manufacturing a luminescent device that can enhance manufacture yield thereof.

It is another feature of the present invention to provide an apparatus for manufacturing a luminescent device that can operate the other parts in case a part of the device is broken down.

An apparatus of manufacturing a luminescent device according to a first embodiment of the present invention includes a depositing section, a sealing section and a buffer cassette. The depositing section deposits a film on each of substrates. The sealing section receives the deposited substrates from the depositing section, and seals the received substrates. The buffer cassette stores the substrates transferred from the depositing section, and is located between the depositing section and the sealing section. The apparatus further includes a first transfer means, a second transfer means, and a third transfer means. The first transfer means transfers the deposited substrates from the depositing section to the sealing section. The second transfer means transfers the deposited substrates from the depositing section to the buffer cassette. The third transfer means transfers the substrates stored in the buffer cassette to the sealing section. The apparatus further includes a controlling section for controlling operation of each of the transfer means to determine transfer route of the substrates. The apparatus further includes a connecting section for connecting the depositing section to the sealing section, and transferring the deposited substrates, wherein the buffer cassette is combined with the connecting section.

An apparatus of manufacturing a luminescent device having a plurality of film forming sections for depositing a film on each of substrates and a sealing section for sealing the deposited substrates according to a second embodiment of the present invention includes at least one buffer cassette for storing the deposited substrates, located between the film forming sections. The apparatus further includes a first transfer means, a second transfer means, and a third transfer means. The first transfer means transfers the deposited substrates between the film forming sections. The second transfer means transfers the deposited substrates from one of the film forming sections to the buffer cassette corresponding to the one. The third transfer means transfers the substrates stored in one of the buffer cassettes to the film forming section corresponding to the one. The apparatus further includes a controlling section for controlling operation of each of the transfer means to determine transfer route of the substrates.

An apparatus of manufacturing a luminescent device according to a third embodiment of the present invention includes a plurality of depositing sections, at least one buffer cassette, and at least one sealing section. The depositing sections deposit a film on each of substrates. The buffer cassette receives part of the deposited substrates from the depositing sections, and stores the received substrates. The sealing section seals the deposited substrates. The apparatus further includes a first transfer means, a second transfer means, and a third transfer means. The first transfer means transfers the deposited substrates from the depositing sections to the sealing section. The second transfer means transfers the deposited substrates from one of the depositing sections to the buffer cassette corresponding to the one. The third transfer means transfers the substrates stored in the buffer cassette to the sealing section. The apparatus further includes a controlling section for controlling operation of each of transfer means to determine transfer route of the substrates. The apparatus further includes a plurality of first connecting sections, a second connecting section, and a plurality transfer means. The first connecting sections connect between the depositing sections. The second connecting section connects one of the depositing sections to the sealing section. The transfer means transfers the deposited substrates between the connecting sections. Here, the buffer cassettes are combined with the connecting sections.

An apparatus for manufacturing a luminescent device having a plurality of depositing sections including film forming sections for depositing films on substrates and a plurality of sealing sections for sealing the deposited substrates according to a fourth embodiment of the present invention includes at least one buffer cassette for storing the deposited substrates, located between the film forming sections. The apparatus further includes a plurality of first transfer means, a plurality of second transfer means, and a plurality of third transfer means. The first transfer means transfers the deposited substrates between the film forming sections. The second transfer means transfers the deposited substrates from one of the film forming sections to the buffer cassette corresponding to the one. The third transfer means transfers the substrates stored in the buffer cassette to the film forming section corresponding to the buffer cassette. The apparatus further includes a controlling section for controlling operation of the transfer means to determine transfer route of the deposited substrates. The apparatus further includes a plurality of first connecting sections for connecting the film forming sections, wherein first buffer cassettes of the buffer cassettes are combined with the first connecting sections. The apparatus further includes a plurality of second connecting sections for connecting the first connecting sections, wherein second buffer cassettes of the buffer cassettes are combined with the first connecting sections.

As described above, an apparatus of manufacturing the luminescent device of the present invention may perform depositing process or sealing process in substrates using a buffer cassette in case a part of the device is broken down.

Therefore, the manufacture yield of the luminescent device is enhanced.

In addition, an apparatus of manufacturing the luminescent device of the present invention includes depositing sections and sealing sections, and so may handle many substrates in a unit time.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a block diagram illustrating an apparatus for manufacturing a luminescent device using a buffer cassette according to the first embodiment of the present invention;

FIG. 2 is a block diagram illustrating the depositing section of FIG. 1;

FIG. 3 is a plan view illustrating the third and fourth film forming sections of FIG. 1;

FIG. 4 is a block diagram illustrating an apparatus for manufacturing the luminescent device using a buffer cassette according to the second embodiment of the present invention;

FIG. 5 is a flowchart illustrating process of manufacturing the luminescent device according to the first embodiment of the present invention;

FIG. 6 is a flowchart illustrating process of manufacturing the luminescent device according to the second embodiment of the present invention;

FIG. 7 is a block diagram illustrating an apparatus of manufacturing a luminescent device according to the third embodiment of the present invention;

FIG. 8 is a block diagram illustrating the first depositing section of FIG. 7;

FIG. 9 is a block diagram illustrating an apparatus of manufacturing the luminescent device according to the fourth embodiment of the present invention;

FIG. 10 is a flowchart illustrating process of manufacturing the luminescent device according to in one embodiment of the present invention in case that one of sealing sections is broken down;

FIG. 11 is a flowchart illustrating process of manufacturing the luminescent device according to one embodiment of the present invention in case that a part of the depositing sections is broken down;

FIG. 12 is a flowchart illustrating process of manufacturing the luminescent device according to another embodiment of the present invention in case that a part of the depositing sections is broken down;

FIG. 13 is a block diagram illustrating an apparatus of manufacturing the luminescent device according to the fifth embodiment of the present invention;

FIG. 14 is a block diagram illustrating an apparatus for manufacturing the luminescent device according to the sixth embodiment of the present invention;

FIG. 15 is a flowchart illustrating process of manufacturing the luminescent device according to one embodiment of the present invention in case that a part of the film forming sections is broken down; and

FIG. 16 is a flowchart illustrating process of manufacturing the luminescent device according to another embodiment of the present invention in case that a part of the film forming sections is broken down.

### DESCRIPTION OF EMBODIMENTS

Hereinafter, the preferred embodiments of the present invention will be explained in more detail with reference to the accompanying drawings.

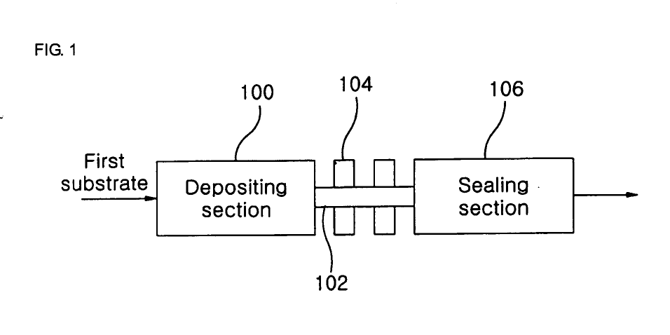

FIG. 1 is a block diagram illustrating an apparatus for manufacturing a luminescent device using a buffer cassette according to the first embodiment of the present invention.

In FIG. 1, the apparatus for manufacturing the luminescent device of the present invention includes a depositing section 100, a first connecting section 102, a buffer cassette 104, and a sealing section 106.

Here, the depositing section 100 and the sealing section 106 are combined in one body.

The depositing section 100 deposits a second film on each first film formed on a plurality of first substrates, thereby producing a plurality of second substrates.

For example, the apparatus of the present invention deposits in sequence an organic layer and a metal line layer on each of Indium Tin Oxide Films (hereinafter, referred to as “ITO films”) formed on the first substrates, thereby producing the second substrates.

Here, the organic layer includes a hole injection layer (HIL), a hole transporting layer (HTL), an emitting layer (EML), an electron transporting layer (ETL), and an electron injection layer (EIL).

For another example, the organic layer includes only the HTL, the EML, and the ETL.

The first connecting section 102 connects the depositing section 100 to the sealing section 106, and transfers the second substrates produced from the depositing section 100 to the sealing section 106.

In addition, the first connecting section 102 adjusts the atmosphere of the depositing section 100 and the sealing section 106.

For example, in the apparatus of the present invention, the first connecting section 102 adjusts the depositing section 100 to vacuum atmosphere, and adjusts the sealing section 106 to nitrogen (N₂) atmosphere. As a result, the sealing section 106 receives stably the second substrates from the depositing section 100, and then seals the received second substrates.

The buffer cassette 104 is combined with the first connecting section 102, stores a certain part of the second substrates produced from the depositing section 100, and transfers the stored second substrates to the sealing section 106.

For example, in case that the process velocity of the depositing section 100 is faster than that of sealing section 102, the buffer cassette 104 stores the second substrates corresponding to difference of the processing velocities of the depositing section 100 and the sealing section 106.

For another example, in case that the sealing section 106 is broken down, the apparatus of the present invention drives continuously the depositing section 100, and stores the second substrates produced from the depositing section 100 to the buffer cassette 104. Here, the buffer cassette 104 may have various structures and sizes in order to store the second substrates.

The apparatus of the present invention includes at least one buffer cassette 104.

The sealing section 106 seals the second substrates transferred from the depositing section 100 or the buffer cassette 104.

In the apparatus of the present invention, the substrates may be transferred by a transfer means, for example, a robot or a conveyer. In other words, the transfer means may have many modifications. However, it will be immediately obvious to those skilled in the art that many modifications of the transfer means do not have any effect to the scope of the present invention

An apparatus for manufacturing the luminescent device according to another embodiment of the present invention further includes a controlling section for controlling operation of the transfer means.

In case that the process velocity of the depositing section 100 differs from that of the sealing section 106, the apparatus of the present invention stores second substrates corresponding to difference of the process velocities of the depositing section 100 and the sealing section 106 in the buffer cassette 104.

Subsequently, the apparatus of the present invention transfers the second substrates stored in the buffer cassette 104 to the sealing section 106 in case that the depositing section 100 is broken down.

The sealing section 106 seals the transferred second substrates.

An apparatus for manufacturing the luminescent device according to still another embodiment of the present invention drives the depositing section 100 though the sealing section 106 is broken down.

Also, the apparatus of the present invention stores the second substrates produced by the depositing section 100 in the buffer cassette 104.

Subsequently, in case that the sealing section 106 is repaired, the sealing section 106 seals the second substrates transferred from the buffer cassette 106.

For another example, the apparatus of the present invention transfers the second substrates stored in the buffer cassette 106 to the sealing section 106 when the depositing section 100 is broken down.

Subsequently, the sealing section 106 seals the second substrates transferred from the buffer cassette 104.

In brief, the apparatus of the present invention further includes the buffer cassette 104 compared with the conventional apparatus. Therefore, in case that one of the depositing section 100 and the sealing section 106 is broken down, the apparatus of the present invention drives the other section using the buffer cassette 104. As a result, the apparatus of the present invention may enhance manufacture yield of the luminescent device.

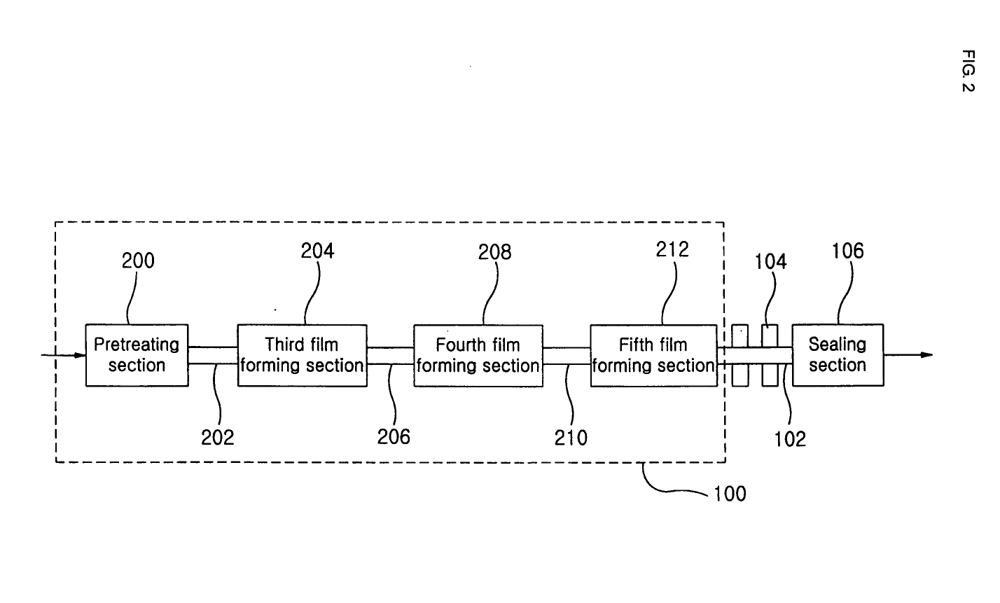

FIG. 2 is a block diagram illustrating the depositing section of FIG. 1.

In FIG. 2, the depositing section 100 includes a pretreating section 200, a second connecting section 202, a third film forming section 204, a third connecting section 206, a fourth film forming section 208, a fourth connecting section 210, and a fifth film forming section 212.

The pretreating section 200 pretreats the first substrates. For example, the pretreating section 200 cleans the first substrates by using water. As a result, the work function of the ITO film is increased. Also, the emitting efficiency of the luminescent device is enhanced.

In another embodiment, the pretreating section 200 oxidizes the surface of the ITO film, and then cleans the oxidized surface of the ITO film.

Subsequently, the pretreating section 200 performs plasma treatment about the cleaned ITO film.

The second connecting section 202 connects the pretreating section 200 to the third film forming section 204.

The third film forming section 204 deposits the HIL and the HTL on the pretreated first substrates.

In another embodiment, the third film forming section 204 deposits only the HTL on the pretreated first substrates.

The HIL injects smoothly holes provided from the ITO film into the HTL.

The HTL transports the injected holes to the EML.

The third connecting section 206 connects the third film forming section 204 to the fourth film forming section 208.

The fourth film forming section 208 deposits the EML on each HTL of the first substrates formed by the third film forming section 204.

In case of a full-colored luminescent device, the fourth film forming section 208 deposits organic material corresponding to red, green, or blue on each HTL of the first substrates.

The fourth connecting section 210 connects the fourth film forming section 208 to the fifth film forming section 212.

The fifth film forming section 212 deposits in sequence the ETL, EIL, and the metal line layer on each EML of the first substrates formed by the fourth film forming section 208.

In another embodiment, the fifth film forming section 212 deposits the ETL and the metal line layer on each EML of the first substrates.

The HIL injects smoothly electrons provided from the metal line layer into the ETL.

The ETL transports the injected electrons to the EML.

In another embodiment, the apparatus of the present invention may include more or less film forming sections than the above film forming sections. However, it will be immediately obvious to those skilled in the art that many modifications of the film forming section do not have any effect to the scope of the present invention

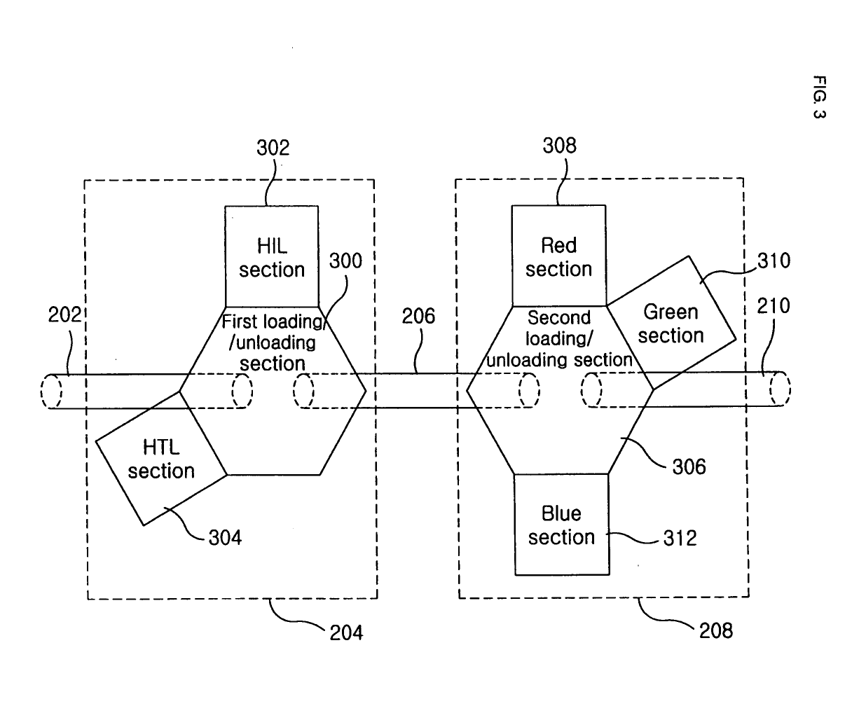

FIG. 3 is a plan view illustrating the third and fourth film forming sections of FIG. 1.

In FIG. 3, the third film forming section 204 includes a first loading/unloading section 300, a HIL section 302, and a HTL section 304.

The HIL section 302 deposits the HIL on each of the first substrates.

The HTL section 304 deposits the HTL on each HIL of the first substrates.

The first loading/unloading section 300 loads the first substrates to the HIL section 302 using a transfer means, for example, a robot.

In addition, the first loading/unloading section 300 unloads the first substrates on which the HILs are deposited, and then loads the unloaded first substrates to the HTL section 304.

Subsequently, the first loading/unloading section 300 unloads the first substrates on which the HTLs are deposited.

The fourth film forming section 208 includes a second loading/unloading section 306, a red section 308, a green section 310, and a blue section 312.

The red section 308 deposits a first organic matter corresponding to red on each HTL of the first substrates formed by the third film forming section 204. As a result, the luminescent device emits light corresponding to red.

The green section 310 deposits a second organic matter corresponding to green on each HTL of the first substrates formed by the third film forming section 204. As a result, the luminescent device emits light corresponding to green.

The blue section 312 deposits a third organic matter corresponding to blue on each HTL of the first substrates formed by the third film forming section 204. As a result, the luminescent device emits light corresponding to blue.

The second loading/unloading section 306 loads the first substrates passing through the third film forming section 204 to the red section 308, the green section 310, or the blue section 312.

In addition, the second loading/unloading section 306 unloads the first substrates on which the organic material is deposited.

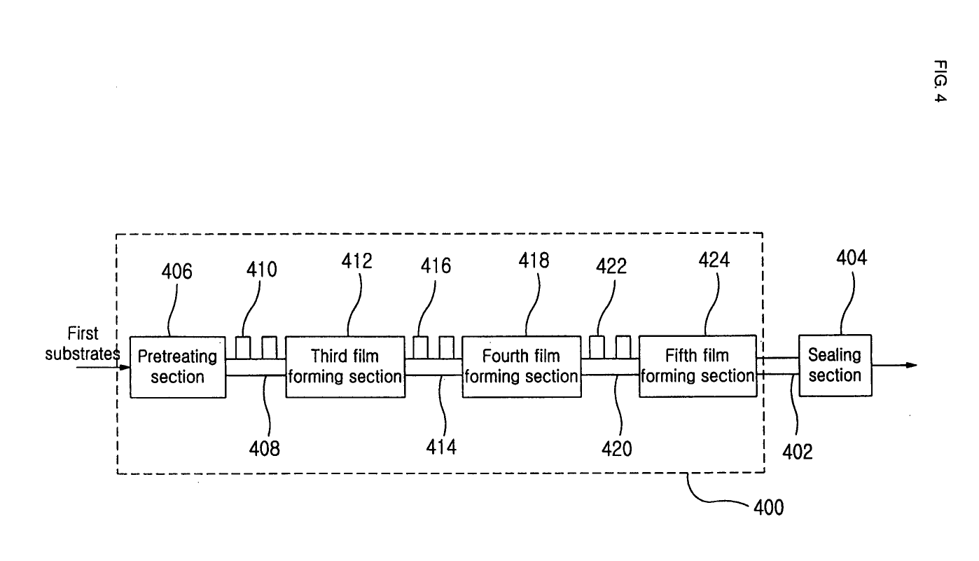

FIG. 4 is a block diagram illustrating an apparatus for manufacturing the luminescent device using a buffer cassette according to the second embodiment of the present invention.

In FIG. 4, the apparatus of the present invention includes a depositing section 400, a first connecting section 402, and a sealing section 404.

The depositing section 400 deposits a second film on each of first films formed on the first substrates, thereby producing second substrates.

The first connecting section 402 connects the depositing section 400 to the sealing section 404.

The sealing section 404 seals the second substrates.

The depositing section 400 includes a pretreating section 406, a second connecting section 408, a first buffer cassette 410, a third film forming section 412, a third connecting section 414, a second buffer cassette 416, a fourth film forming section 418, a fourth connecting section 420, a third buffer cassette 422, and a fifth film forming section 424.

The pretreating section 406 pretreats the first substrates having the first film.

For example, the pretreating section 406 cleans the first substrates having ITO film.

The second connecting section 408 connects the pretreating section 406 to the third film forming section 412, and transfers the pretreated first substrates to the first buffer cassette 410 and the third film forming section 412 using a transfer means.

For example, in case that the third film forming section 412 is broken down, the second connecting section 408 transfers the pretreated first substrates to the first buffer cassette 410.

Whereas, in case that the third film forming section 412 is not broken down, the second connecting section 408 transfers the pretreated first substrates to the third film forming section 412.

For another example, in case that the process velocity of the pretreating section 406 is faster than that of the third film forming section 412, a certain part of the pretreated first substrates is transferred to the first buffer cassette 410, and the other first substrates are transferred to the third film forming section 412.

The first buffer cassette 410 stores the pretreated first substrates transferred from the pretreating section 406, and then sends the stored first substrates to the third film forming section 412.

The third film forming section 412 deposits a third film on each of the pretreated first substrates. For example, the third film forming section 412 deposits in sequence a HIL and a HTL on each of the pretreated first substrates.

The third connecting section 414 connects the third film forming section 412 to the fourth film forming section 418, and transfers the first substrates having the third film to the second buffer cassette 416 and the fourth film forming section 418 by using a transfer means.

For example, in case that the fourth film forming section 418 is broken down, the first substrates having the third film is transferred to the second buffer cassette 416.

However, in case that the fourth film forming section 418 is not broken down, the first substrates having the third film are transferred to the fourth film forming section 418.

For another example, the process velocity of the third film forming section 412 is faster than that of the fourth film forming section 418, a part of the first substrates having the third film is transferred to the second buffer cassette 416, and the other first substrates are transferred to the fourth film forming section 418.

The second buffer cassette 416 stores the first substrates having the third film, and then sends the stored first substrates to the fourth film forming section 418.

The fourth film forming section 418 deposits a fourth film on each third film of the first substrates. For example, the fourth film forming section 418 deposits organic material corresponding to red, green, or blue on each third film of the first substrates.

The fourth connecting section 420 connects the fourth film forming section 418 to the fifth film forming section 424, and transfers the first substrates having the fourth film to the third buffer cassette 422 and the fifth film forming section 424 by using a transfer means.

For example, in case that the fifth film forming section 424 is broken down, the first substrates having the fourth film are transferred to the third buffer cassette 422.

However, in case that the fifth film forming section 424 is not broken down, the first substrates having the fourth film are transferred to the fifth film forming section 424.

For another example, in case that the process velocity of the fourth film forming section 418 is faster than that of the fifth film forming section 424, a part of the first substrates having the fourth film is transferred to the third buffer cassette 422, and the other first substrates are transferred to the fifth film forming section 424.

The third buffer cassette 422 stores the first substrates having the fourth film, and then sends the stored first substrates to the fifth film forming section 424.

The fifth film forming section 424 deposits a fifth film on each of the fourth films of the first substrates, thereby producing the second substrates.

For example, the fifth film forming section 424 deposits in sequence the ETL and the metal line layer on each of the fifth films of the first substrates.

The second film corresponds to the third, fourth, and fifth films deposited in sequence.

Though a part of the apparatus of the present invention is broken down, the apparatus drives the other elements by using the buffer cassettes 410, 416, and 422. Hence, the manufacture yield of the luminescent device is enhanced.

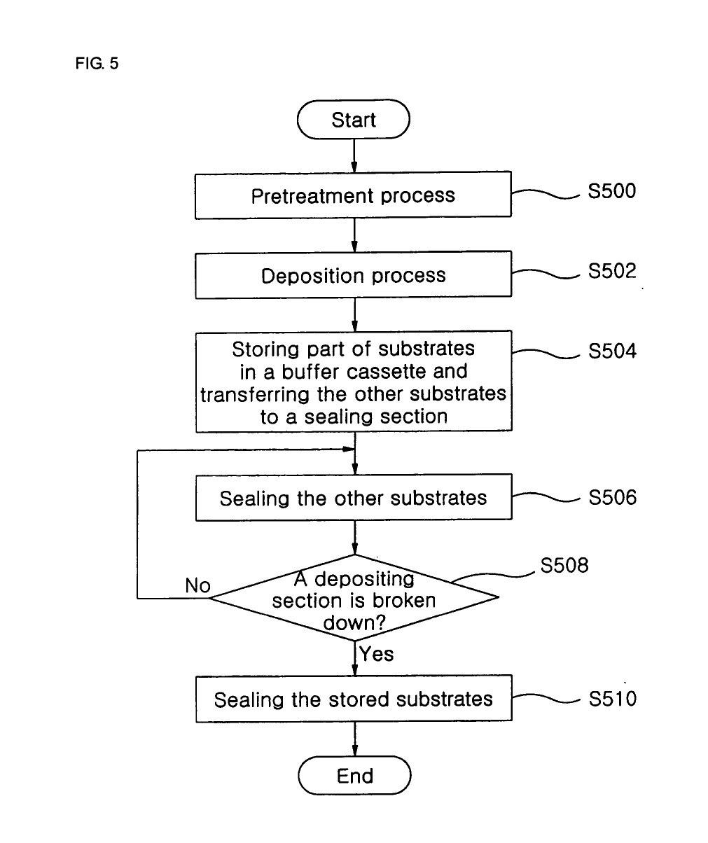

FIG. 5 is a flowchart illustrating process of manufacturing the luminescent device according to the first embodiment of the present invention.

As shown in FIG. 5, in step S500, the first substrates having the first film are pretreated.

In step S502, the second film is deposited on each of the pretreated first substrates, and so the second substrates are produced from the depositing section 100.

In step S504, a part of the second substrates is stored in the buffer cassette 104, and the other second substrates are transferred to the sealing section 106.

In step S506, the other second substrates are sealed by the sealing section 106.

In step S508, it is determined whether or not the depositing section 100 is broken down.

In case that the depositing section 100 is not broken down, the step S506 is conducted again.

In step S510, in case that the depositing section 100 is broken down, the second substrates stored in the buffer cassette 104 are transferred to the sealing section 106, and then the transferred second substrates are sealed by the sealing section 106.

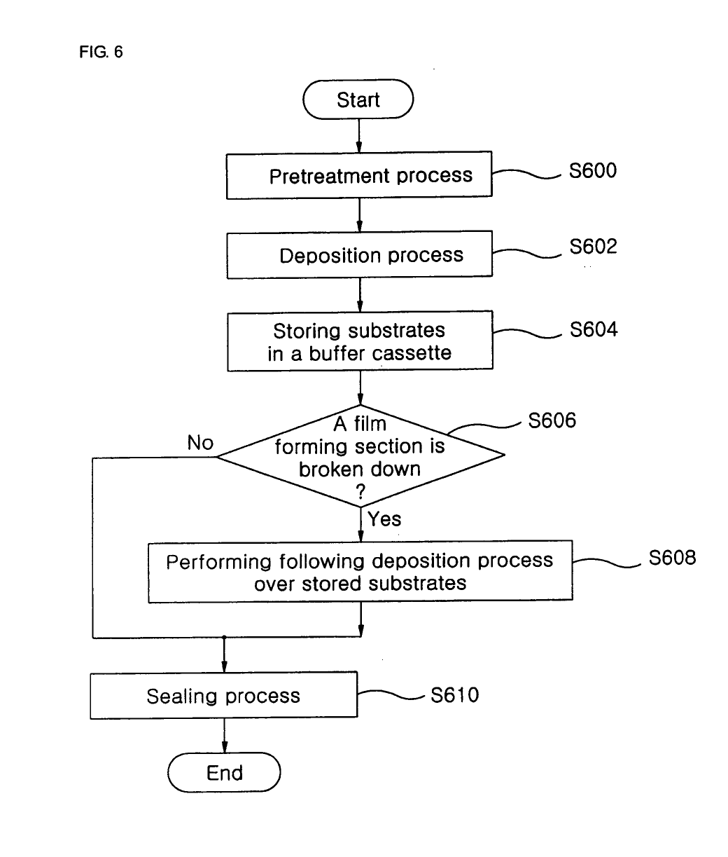

FIG. 6 is a flowchart illustrating process of manufacturing the luminescent device according to the second embodiment of the present invention.

In FIG. 6, in step S600, the first substrates are pretreated.

In step S602, a first depositing process is performed about the pretreated first substrates.

In step S604, the first substrates having predetermined film formed by the first depositing process are stored in the buffer cassette.

In step S606, it is determined whether or not the film forming section is broken down.

In step S610, in case that the film forming section is not broken down, the second film is deposited on each on the first substrates, and so the second substrates are produced.

Subsequently, the second substrates are sealed.

In step S608, in case that the film forming section is broken down, a second depositing process following the first depositing process is performed to the first substrates, and so the second substrates are produced.

In step S610, the second substrates are sealed.

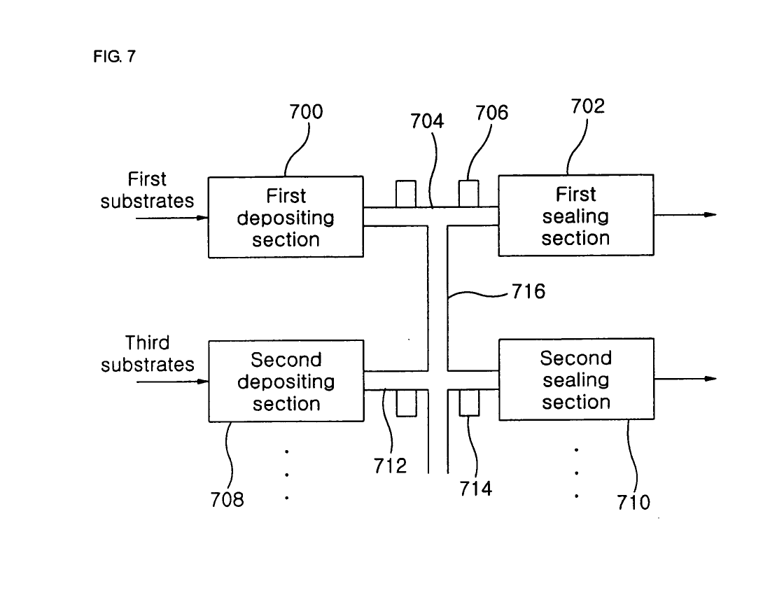

FIG. 7 is a block diagram illustrating an apparatus of manufacturing the luminescent device according to the third embodiment of the present invention.

In FIG. 7, the apparatus of the present invention includes a first depositing section 700, a first sealing section 702, a first connecting section 704, a first buffer cassette 706, a second depositing section 708, a second sealing section 710, a second connecting section 712, and a second buffer cassette 714.

The apparatus according to one embodiment of the present invention is one for manufacturing an organic electroluminescent device.

The first depositing section 700 deposits a second film on each of first films formed on first substrates, thereby producing second substrates having a first luminescent device. In the apparatus of the present invention, the first film includes an ITO film.

The first film according to another embodiment of the present invention includes the ITO film, an insulting layer, and a dam.

The second film includes a HTL, an EML, an ETL, and a metal line layer.

The second film according to another embodiment of the present invention includes a HIL, a HTL, an EML, an ETL, an EIL, and a metal line layer.

The first connecting section 704 transfers the second substrates produced from the first depositing section 700 to the first buffer cassette 706 and/or the first sealing section 702 by using a transfer means. Here, the transfer means is a robot, a conveyer, etc.

For example, in case that the first sealing section 702 is not broken down, the first connecting section 704 transfers the second substrates to the first sealing section 702. However, in case that the first sealing section 702 is broken down, the first connecting section 704 transfers the second substrates to the first buffer cassette 706.

For another example, in case that the process velocity of the first depositing section 700 is faster than that of the first sealing section 702, the first connecting section 704 transfers a part of the second substrates to the first buffer cassette 706.

In addition, the first connecting section 704 transfers the other second substrates to the first sealing section 702.

The first buffer cassette 706 is combined with the first connecting section 704, and stores a part of the second substrates produced from the first depositing section 700.

Additionally, the first buffer cassette 706 transfers the stored second substrates to the first sealing section 702 in case that the first depositing section 700 is broken down, and to the second sealing section 710 in case that the second depositing section 708 is broken down.

The first sealing section 702 seals the second substrates transferred from the first depositing section 700 or the first buffer cassette 706.

In addition, the first sealing section 702 seals fourth substrates transferred from the second depositing section 708 or the second buffer cassette 714.

For example, in case that the first depositing section 700 is broken down, the first sealing section 702 seals the second substrates transferred from the first buffer cassette 706, and/or the fourth substrates transferred from the second depositing section 708 or the second buffer cassette 714. Here, it is desired that the fourth substrates are identical to the second substrates.

The second depositing section 708 deposits a fourth film on each of the third films formed on the third substrates, thereby producing fourth substrates.

Here, the third substrates and the third films are substantially identical to the first substrates and the first films, respectively.

Additionally, the fourth substrates and the fourth films are substantially identical to the second substrates and the second films, respectively.

In other words, the first luminescent device is substantially identical to the second luminescent device.

The second connecting section 712 transfers the fourth substrates produced from the second depositing section 708 to the second buffer cassette 714 and the second sealing section 710 by using a transfer means. Here, the transfer means includes a robot, conveyer, etc.

For example, in case that the second sealing section 710 is not broken down, the second connecting section 712 transfers the fourth substrates to the second sealing section 710. However, in case that the second sealing section 710 is broken down, the second connecting section 712 transfers the fourth substrates to the second buffer cassette 714.

For another example, in case that the process velocity of the second depositing section 708 is faster than that of the second sealing section 710, the second connecting section 712 transfers a part of the fourth substrates to the second buffer cassette 714.

In addition, the second connecting section 712 transfers the other fourth substrates to the second sealing section 710.

The second buffer cassette 714 is combined with the second connecting section 712, and stores a part of the fourth substrates.

Additionally, the second buffer cassette 714 transfers the stored fourth substrates to the second sealing section 710 in case that the second depositing section 708 is broken down, and to the first sealing section 702 in case that the first depositing section 700 is broken down.

The second sealing section 710 seals the fourth substrates transferred from the second depositing section 708 or the second buffer cassette 714.

In addition, the second sealing section 710 seals the second substrates transferred from the first depositing section 700 or the first buffer cassette 706.

For example, in case that the second depositing section 708 is broken down, the second sealing section 710 seals the fourth substrates transferred from the second buffer cassette 714, and/or the second substrates transferred from the first depositing section 700 or the first buffer cassette 706.

In short, in case that a part of the first depositing section 700, the first sealing section 702, the second depositing section 708, and the second sealing section 710 is broken down, the apparatus of the present invention drives the other sections by using the buffer cassettes 706 and 714. As a result, the apparatus of the present invention may enhance the manufacture yield of the luminescent device.

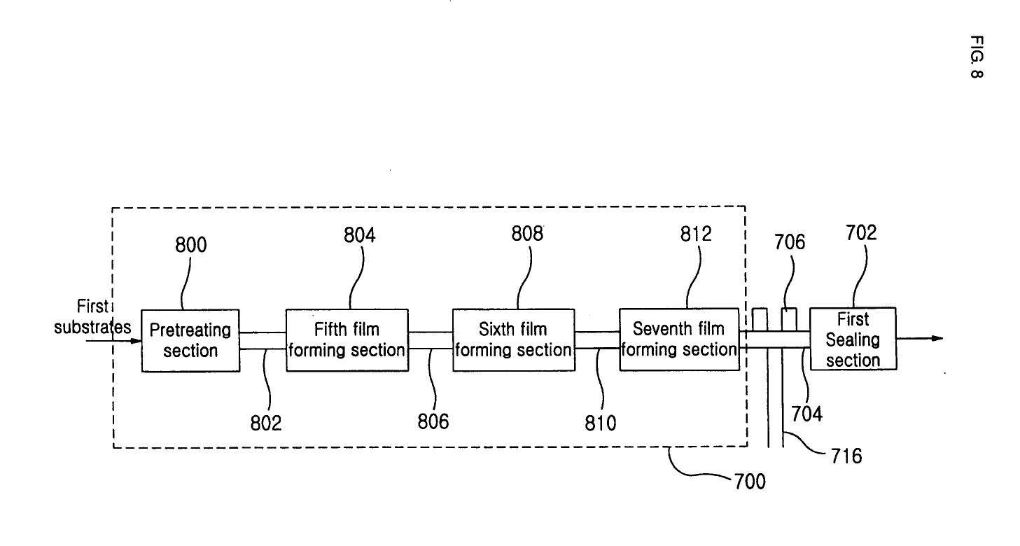

FIG. 8 is a block diagram illustrating the first depositing section of FIG. 7.

In FIG. 8, the first depositing section 700 includes a pretreating section 800, a fourth connecting section 802, a fifth film forming section 804, a fifth connecting section 806, a sixth film forming section 808, a sixth connecting section 810, and a seventh film forming section 812.

The pretreating section 800 pretreats the first substrates.

For example, the pretreating section 800 cleans the first substrates by using water. As a result, the work function of the ITO film is increased. Also, the emitting efficiency of the luminescent device is enhanced.

In another embodiment, the pretreating section 800 oxidizes the surface of the ITO film, and then cleans the oxidized surface of the ITO film.

Subsequently, the pretreating section 800 performs plasma treatment to the cleaned ITO film.

The fourth connecting section 802 connects the pretreating section 800 to the fifth film forming section 804.

The fifth film forming section 804 deposits the HIL and the HTL on each of the pretreated first substrates.

In another embodiment, the fifth film forming section 804 deposits only the HTL on each of the pretreated first substrates.

The fifth connecting section 806 connects the fifth film forming section 804 to the sixth film forming section 808.

The sixth film forming section 808 deposits the EML on each HTL of the first substrates formed by the fifth film forming section 804.

In case of a full-colored luminescent device, the sixth film forming section 808 deposits organic material corresponding to red, green, or blue on each HTL of the first substrates.

The sixth connecting section 810 connects the sixth film forming section 808 to the seventh film forming section 812.

The seventh film forming section 812 deposits in sequence the ETL, the EIL, and the metal line layer on each EML of the first substrates.

In another embodiment, the seventh film forming section 812 deposits in sequence the ETL and the metal line layer on each EML of the first substrates.

Here, the second film corresponds to the fifth, sixth and seventh films deposited in sequence on the EML.

In another apparatus of the present invention may include more or less film forming sections than the above film forming sections. However, it will be immediately obvious to those skilled in the art that many modifications of the film forming section do not have any effect to the scope of the present invention

The second depositing section 708 is not shown, but is similar to the constitution of the first depositing section 700.

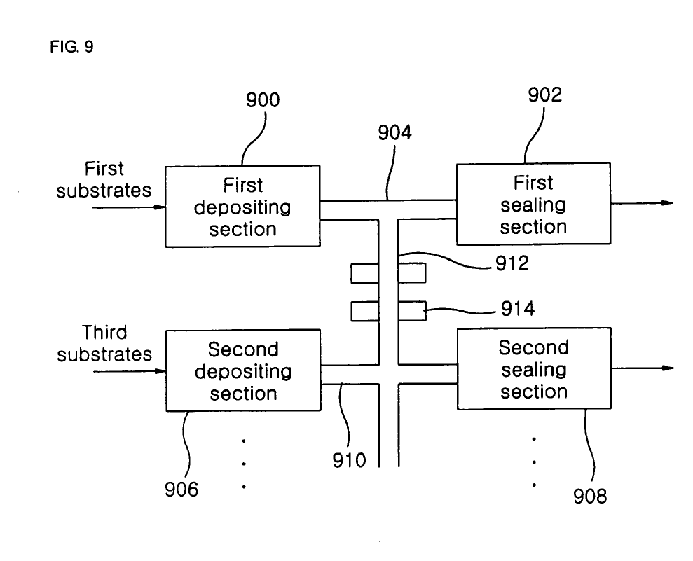

FIG. 9 is a block diagram illustrating an apparatus of manufacturing the luminescent device according to the fourth embodiment of the present invention.

In FIG. 9, the apparatus of the present invention includes a first depositing section 900, a first sealing section 902, a first connecting section 904, a second depositing section 906, a second sealing section 908, a second connecting section 910, a third connecting section 912, and a third buffer cassette 914.

The first depositing section 900 deposits a second film on each of first films formed on first substrates, thereby producing second substrates having a first luminescent device.

The first connecting section 904 transfers the produced second substrates to the first sealing section 902, and transfers fourth substrates provided from the third buffer cassette 914 or the second depositing section 906 to the first sealing section 902 by using a transfer means.

A sealing section 902 seals the second substrates or the fourth substrates transferred through the first connecting section 904.

The second depositing section 906 deposits a fourth film on each of third films formed on the third substrates, thereby producing the fourth substrates having a second luminescent device. Here, it is desirable that the third films and the fourth films are substantially identical to the first films and the second films, respectively.

In other words, the second luminescent device is substantially identical to the first luminescent device.

The second connection section 910 transfers the produced fourth substrates to the second sealing section 908, and transfers the second substrates provided from the third buffer cassette 914 or the first depositing section 900 to the second sealing section 908 by using a transfer means.

The second sealing section 908 seals the second substrates or the fourth substrates transferred through the second connecting section 910.

The third connecting section 912 connects the first connecting section 904 to the second connecting section 910, and transfers the second substrates and the fourth substrates to the second connecting section 910 and the first connecting section 904.

The third buffer cassette 914 stores the second substrates transferred from the first depositing section 900 or the fourth substrates transferred from the second depositing section 906.

In one embodiment of the present invention, in case that the first sealing section 902 is broken down, the second substrates produced from the first depositing section 900 are stored in the third buffer cassette 914.

In case that the process velocity of the first depositing section 900 is faster than that of the first sealing section 902, a part of the second substrates produced from the first depositing section 900 is transferred to the third buffer cassette 914.

In addition, the other second substrates are transferred to the first sealing section 902.

In another embodiment of the present invention, in case that the second sealing section 908 is broken down, the fourth substrates produced from the second depositing section 906 are stored in the third buffer cassette 914.

In case that the process velocity of the second depositing section 906 is faster than that of the second sealing section 908, a part of the fourth substrates produced from the second depositing section 906 is transferred to the third buffer cassette 914.

Additionally, the other fourth substrates are transferred to the second sealing section 908.

In still another embodiment of the present invention, in case that the first depositing section 900 is broken down, the second substrates or the fourth substrates stored in the third buffer cassette 914 are transferred to the first sealing section 902, or a part of the fourth substrates produced from the second depositing section 906 is transferred to the first sealing section 902.

In brief, the apparatus of the present invention further includes the third buffer cassette 914 compared with the conventional apparatus. Therefore, in case that a part of the apparatus of the present invention is broken down, the apparatus of the present invention drives the other sections by using the third buffer cassette 914. As a result, the apparatus of the present invention may enhance the manufacture yield of the luminescent device.

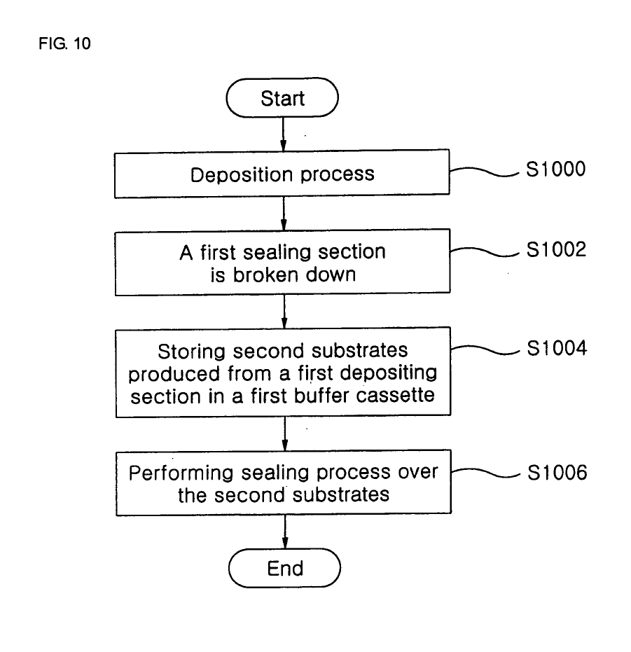

FIG. 10 is a flowchart illustrating process of manufacturing the luminescent device in case that one of sealing sections is broken down according to one embodiment of the present invention.

In FIG. 10, in step S1000, the first depositing section 700 deposits the second film on each of the first films of the first substrates, and the second depositing section 708 deposits the fourth film on each of the third films of the third substrates.

In step S1002, the first sealing section 702 is broken down.

In step S1004, the second substrates produced from the first depositing section 700 are stored in the first buffer cassette 706, or transferred to the second sealing section 710.

In step S1006, the second sealing section 710 seals the transferred second substrates.

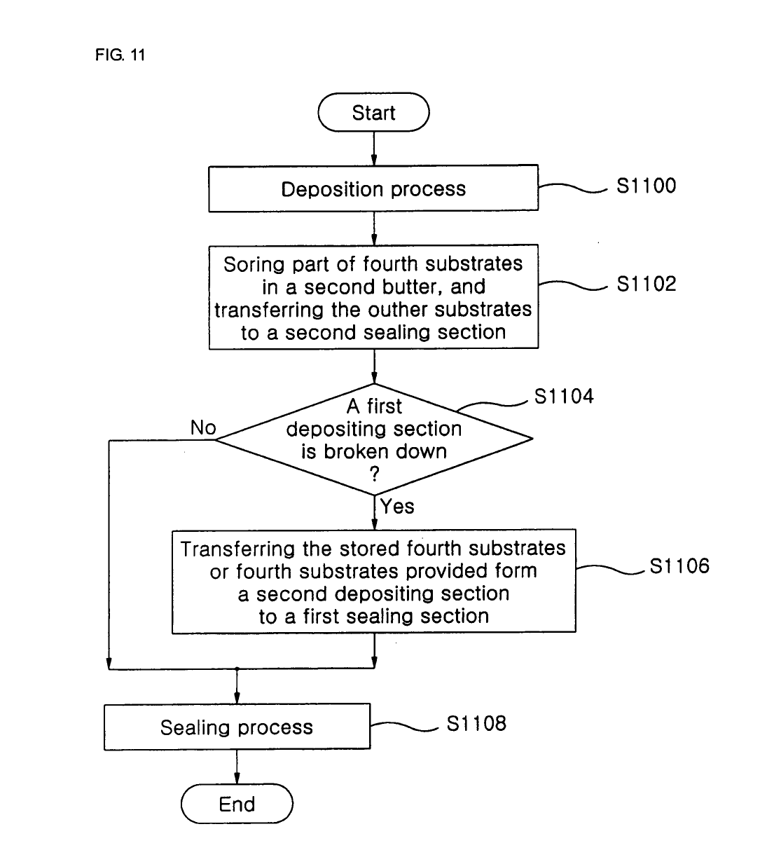

FIG. 11 is a flowchart illustrating process of manufacturing the luminescent device in case that a part of the depositing sections is broken down according to one embodiment of the present invention.

In FIG. 11, in step S1100, the first depositing section 700 deposits the second film on each of the first films of the first substrates.

In addition, the second depositing section 708 deposits the fourth film on each of the third films of the third substrates.

In step S1102, in case that the process velocity of the second depositing section 708 is faster than that of the second sealing section 710, a part of the fourth substrates produced from the second depositing section 708 is stored in the second buffer cassette 714, and the other fourth substrates are transferred to the second sealing section 710.

In step S1104, it is determined whether or not the first depositing section 700 is broken down.

In case that the first depositing section 700 is not broken down, the second substrates produced from the first depositing section 700 are transferred to the first sealing section 702.

In step S1106, in case that the first depositing section 700 is broken down, the fourth substrates stored in the second buffer cassette 714 or the fourth substrates produced from the second depositing section 708 are transferred to the first sealing section 702.

In step S1108, the first sealing section 702 seals the transferred fourth substrates.

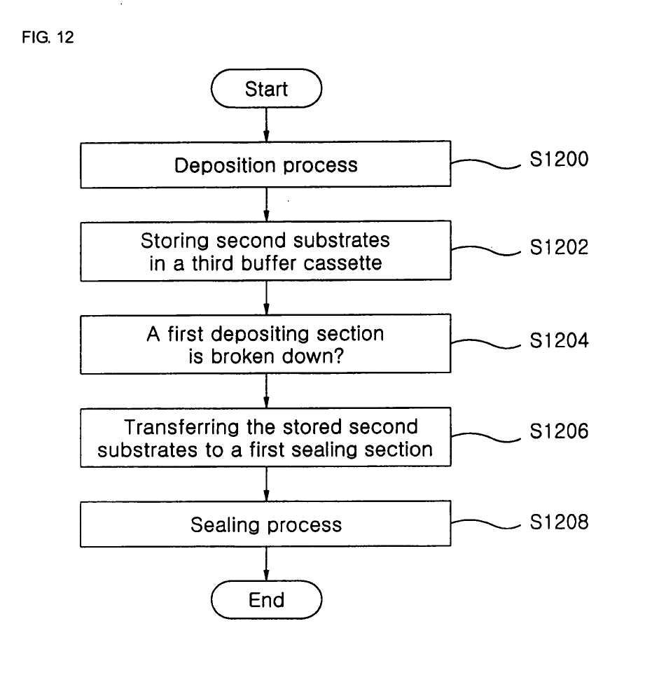

FIG. 12 is a flowchart illustrating process of manufacturing the luminescent device in case that a part of the depositing sections is broken down according to another embodiment of the present invention.

In FIG. 12, in step S1200, the first depositing section 900 deposits the second film on each of the first films of the first substrates.

Additionally, the second depositing section 906 deposits the fourth film on each of the third films of the third substrates.

In step S1202, the second substrates produced from the first depositing section 900 are stored in the third buffer cassette 914.

In step S1204, the first depositing section 900 is broken down.

In step S1206, the second substrates stored in the third buffer cassette 914 are transferred to the first sealing section 902.

In step S1208, the first sealing section 902 seals the transferred second substrates.

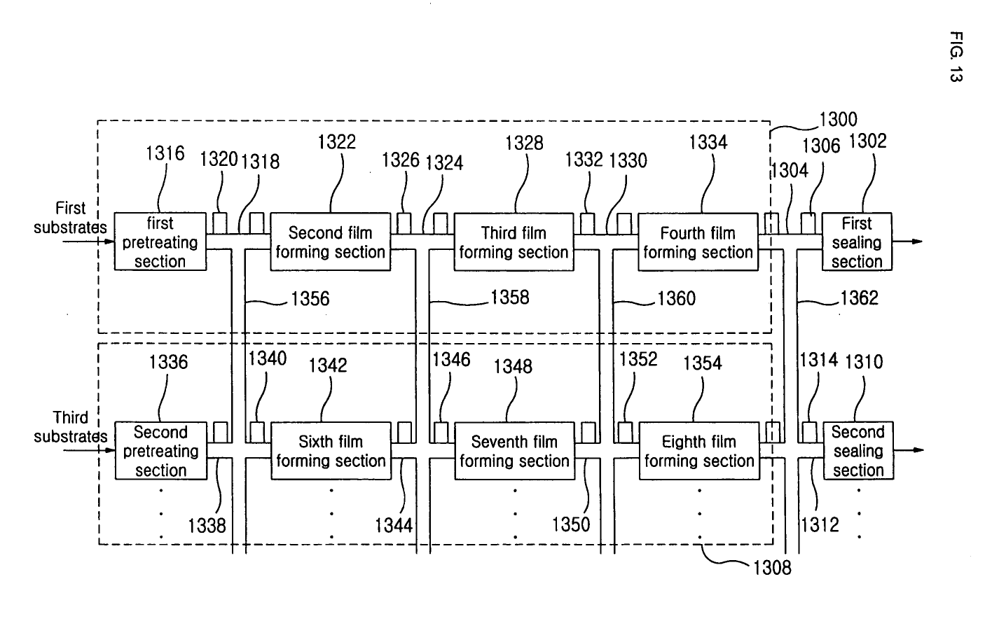

FIG. 13 is a block diagram illustrating an apparatus of manufacturing the luminescent device according to the fifth embodiment of the present invention.

In FIG. 13, the apparatus of the present invention includes a first depositing section 1300, a first sealing section 1302, a first connecting section 1304, a first buffer cassette 1306, a second depositing section 1308, a second sealing section 1310, a second connecting section 1312, and a second buffer cassette 1314.

The first depositing section 1300 includes a first pretreating section 1316, a third connecting section 1318, a third buffer cassette 1320, a second film forming section 1322, a fourth connecting section 1324, a fourth buffer cassette 1326, a third film forming section 1328, a fifth connecting section 1330, a fifth buffer cassette 1332, and a fourth film forming section 1334.

The apparatus according to one embodiment of the present invention is one for manufacturing an organic electroluminescent device.

A second depositing section 1308 includes a second pretreating section 1336, a sixth connecting section 1338, a sixth buffer cassette 1340, a sixth film forming section 1342, a seventh connecting section 1344, a seventh buffer cassette 1346, a seventh film forming section 1348, an eighth connecting section 1350, an eighth buffer cassette 1352, and an eighth film forming section 1354.

The first pretreating section 1316 pretreats first substrates having a first film.

For example, the first film includes an ITO film.

For another example, the first film includes an ITO film, an insulting layer, and a dam.

In particular, the first pretreating section 1316 cleans the first substrates by using water. As a result, the work function of the ITO film is increased. Also, the emitting efficiency of the luminescent device is enhanced.

In another embodiment, the first pretreating section 1316 oxidizes the surface of the ITO film, and then cleans the oxidized surface of the ITO film.

Subsequently, the first pretreating section 1316 performs plasma treatment about the cleaned ITO film.

The third connecting section 1318 connects the first pretreating section 1316 to the second film forming section 1322, and transfers the pretreated first substrates to the third buffer cassette 1320, the second film forming section 1322, or the sixth film forming section 1342 by using a transfer means.

For example, in case that the process velocity of the first pretreating section 1316 is faster than that of the second film forming section 1322, the third connecting section 1318 transfers a part of the pretreated first substrates to the third buffer cassette 1320, and transfers the other pretreated first substrates to the second film forming section 1322.

For another example, in case that the second film forming section 1322 is broken down, the third connecting section 1318 transfers the pretreated first substrates to the third buffer cassette 1320 or the sixth film forming section 1342.

The third buffer cassette 1320 stores the pretreated first substrates, and transfers the stored first substrates to the second film forming section 1322 or the sixth film forming section 1342.

The second film forming section 1322 deposits a second film on each of first films of the pretreated first substrates.

In one embodiment, the second film includes a HIL and a HTL.

In another embodiment, the second film includes only a HTL.

The fourth connecting section 1324 connects the second film forming section 1322 to the third film forming section 1328, and transfers the first substrates having the second film to the fourth buffer cassette 1326, the third film forming section 1328 or the seventh film forming section 1348 by using a transfer means.

For example, in case that the process velocity of the second film forming section 1322 is faster than that of the third film forming section 1328, the fourth connecting section 1324 transfers a part of the first substrates having the second film to the fourth buffer cassette 1326, and transfers the other first substrates to the third film forming section 1328.

For another example, in case that the third film forming section 1328 is broken down, the fourth connecting section 1324 transfers the first substrates having the second film to the fourth buffer cassette 1326 or the seventh film forming section 1348.

The fourth buffer cassette 1326 stores the first substrates having the second film.

In addition, the fourth buffer cassette 1326 transfers the stored first substrates to the third film forming section 1328 or the seventh film forming section 1348.

The third film forming section 1328 deposits a third film on each of the second films of the first substrates.

In one embodiment, the third film includes an EML.

The fifth connecting section 1330 connects the third film forming section 1328 to the fourth film forming section 1334, and transfers the first substrates having the third film to the fifth buffer cassette 1332, the fourth film forming section 1334, or the eighth film forming section 1354 by using a transfer means.

For example, in case that the process velocity of the third film forming section 1328 is faster than that of the fourth film forming section 1334, the fifth connecting section 1330 transfers a part of the first substrates having the third film to the fifth buffer cassette 1332, and transfers the other first substrates to the fourth film forming section 1334.

For another example, in case that the fourth film forming section 1334 is broken down, the fifth connecting section 1330 transfers the first substrates having the third film to the fifth buffer cassette 1332 or the eighth film forming section 1354.

The fifth buffer cassette 1332 stores the first substrates having the third film.

Moreover, the fifth buffer cassette 1332 transfers the stored first substrates to the fourth film forming section 1334 or the eighth film forming section 1354.

The fourth film forming section 1334 deposits a fourth film on each of the third films of the first substrates, thereby producing second substrates having a first luminescent device.

In one embodiment, the fourth film includes an ETL, an EIL, and a metal line layer.

In another embodiment, the fourth film includes only an ETL and a metal line layer.

The first connecting section 1304 connects the fourth film forming section 1334 to the first sealing section 1302, and transfers the second substrates to the first buffer cassette 1306, the first sealing section 1302, and the second sealing section 1310 by using a transfer means.

For example, in case that the process velocity of the fourth film forming section 1334 is faster than that of the first sealing section 1302, the first connecting section 1304 transfers a part of the second substrates to the first buffer cassette 1306, and transfers the other second substrates to the first sealing section 1302.

For another example, in case that the first sealing section 1302 is broken down, the first connecting section 1304 transfers the second substrates to the first buffer cassette 1306 or the second sealing section 1310.

The first buffer cassette 1306 stores the second substrates, and then transfers the stored second substrates to the first sealing section 1302 or the second sealing section 1310.

The first sealing section 1302 seals the transferred second substrates.

The second pretreating section 1336 pretreats third substrates having a fifth film. Here, the fifth film is substantially identical to the first film.

The sixth connecting section 1338 connects the second pretreating section 1336 to the sixth film forming section 1342, and transfers the pretreated third substrates to the sixth buffer cassette 1340, the sixth film forming section 1342, or the second film forming section 1322 by using a transfer means.

For example, in case that the process velocity of the second pretreating section 1336 is faster than that of the sixth film forming section 1342, the sixth connecting section 1338 transfers a part of the pretreated third substrates to the sixth buffer cassette 1340, and transfers the other third substrates to the sixth film forming section 1342.

For another example, in case that the sixth film forming section 1342 is broken down, the sixth connecting section 1338 transfers the pretreated third substrates to the sixth buffer cassette 1340 or the second film forming section 1322.

The sixth buffer cassette 1340 stores the pretreated third substrates, and transfers the stored third substrates to the sixth film forming section 1342 or the second film forming section 1322.

The sixth film forming section 1342 deposits a sixth film on each of the fifth films of the pretreated third substrates. Here, the sixth film is substantially identical to the second film.

The seventh connecting section 1344 connects the sixth film forming section 1342 to the seventh film forming section 1348, and transfers the third substrates having the sixth film to the seventh buffer cassette 1346, the seventh film forming section 1348 or the third film forming section 1328 by using a transfer means.

For example, in case that the process velocity of the sixth film forming section 1342 is faster than that of the seventh film forming section 1348, the seventh connecting section 1344 transfers a part of the third substrates having the sixth film to the seventh buffer cassette 1346, and transfers the other third substrates to the seventh film forming section 1348.

For another example, in case that the seventh film forming section 1348 is broken down, the seventh connecting section 1344 transfers the third substrates having the sixth film to the seventh buffer cassette 1346 or the third film forming section 1328 by using a transfer means.

The seventh buffer cassette 1346 stores the third substrates having the sixth film.

In addition, the seventh buffer cassette 1346 transfers the stored third substrates to the seventh film forming section 1348 or the third film forming section 1328.

The seventh film forming section 1348 deposits a seventh film on each of the sixth films of the third substrates. Here, the seventh film is substantially identical to the third film.

The eighth connecting section 1350 connects the seventh film forming section 1348 to the eighth film forming section 1354, and transfers the third substrates having the seventh film to the eighth buffer cassette 1352, the eighth film forming section 1354, or the fourth film forming section 1334 by using a transfer means.

For example, in case that the process velocity of the seventh film forming section 1348 is faster than that of the eighth film forming section 1354, the eighth connecting section 1350 transfers a part of the third substrates having the seventh film to the eighth buffer cassette 1352, and transfers the other third substrates to the eighth film forming section 1354.

For another example, in case that the eighth film forming section 1354 is broken down, the eighth connecting section 1350 transfers the third substrates having the seventh film to the eighth buffer cassette 1352 or the fourth film forming section 1334.

The eighth buffer cassette 1352 stores the third substrates having the seventh film

In addition, the eighth buffer cassette 1352 transfers the stored third substrates to the eighth film forming section 1354 or the fourth film forming section 1334.

The eighth film forming section 1354 deposits an eighth film on each of the seventh films of the third substrates, thereby producing fourth substrates having a second luminescent device. Here, the eighth film is substantially identical to the fourth film.

Additionally, the first substrates and the second substrates are substantially identical to the third substrates and the fourth substrates, respectively.

Moreover, the second luminescent device is substantially identical to the first luminescent device.

The second connecting section 1312 connects the eighth film forming section 1354 to the second sealing section 1310, and transfers the fourth substrates to the second buffer cassette 1314, the second sealing section 1310, or the first sealing section 1302 by using a transfer means.

For example, in case that the process velocity of the eighth film forming section 1354 is faster than that of the second sealing section 1310, the second connecting section 1312 transfers a part of the fourth substrates to the second buffer cassette 1314, and transfers the other fourth substrates to the second sealing section 1310.

For another example, in case that the second sealing section 1310 is broken down, the second connecting section 1314 transfers the fourth substrates to the second buffer cassette 1314 or the first sealing section 1302.

The second buffer cassette 1314 stores the fourth substrates, and then transfers the stored fourth substrates to the second sealing section 1310 or the first sealing section 1302.

The second sealing section 1310 seals the fourth substrates.

A ninth connecting section 1356 connects the third connecting section 1318 to the sixth connecting section 1338.

A tenth connecting section 1358 connects the fourth connecting section 1324 to the seventh connecting section 1344.

An eleventh connecting section 1360 connects the fifth connecting section 1330 to the eighth connecting section 1350.

A twelfth connecting section 1362 connects the first connecting section 1304 to the second connecting section 1312.

In short, the apparatus of the present invention further includes the buffer cassettes 1306, 1314, 1320, 1326, 1332, 1340, 1346 and 1352 compared with the conventional apparatus. Therefore, in case that a part of the depositing sections 1300 and 1308 is broken down, the apparatus of the present invention drives the other sections by using the buffer cassettes 1306, 1314, 1320, 1326, 1332, 1340, 1346 and 1352. As a result, the apparatus of the present invention may enhance the manufacture yield of the luminescent device.

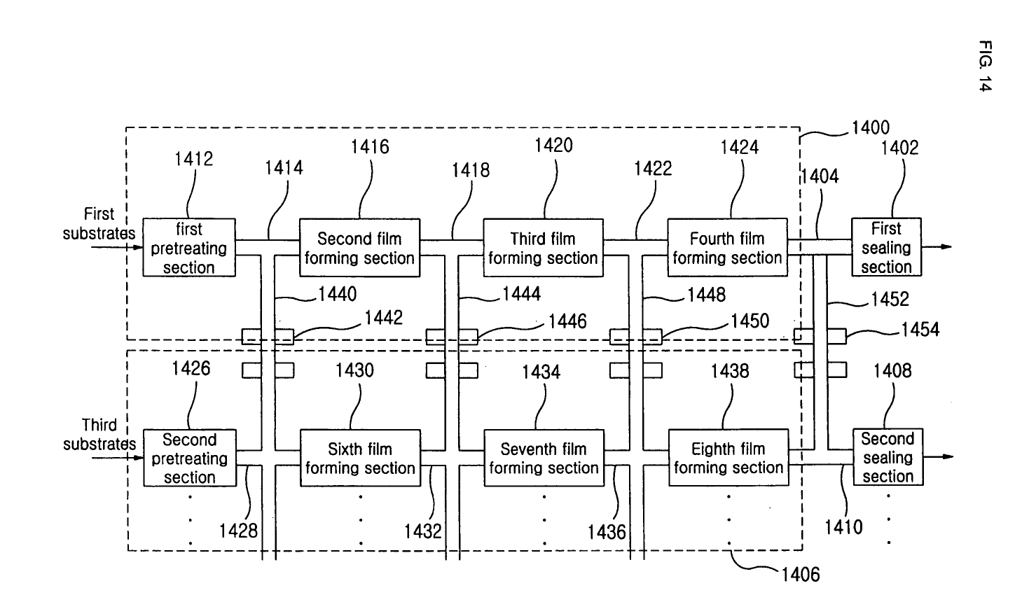

FIG. 14 is a block diagram illustrating an apparatus for manufacturing the luminescent device according to the sixth embodiment of the present invention.

In FIG. 14, the apparatus of the present invention includes a first depositing section 1400, a first sealing section 1402, a first connecting section 1404, a second depositing section 1406, a second sealing section 1408, a second connecting section 1410, a ninth connecting section 1440, a first buffer cassette 1442, a tenth connecting section 1444, a second buffer cassette 1446, an eleventh connecting section 1448, a third buffer cassette 1450, a twelfth connecting section 1452, and a fourth buffer cassette 1454.

The apparatus according to one embodiment of the present invention is one for manufacturing an organic electroluminescent device.

The first depositing section 1400 includes a first pretreating section 1412, a third connecting section 1414, a second film forming section 1416, a fourth connecting section 1418, a third film forming section 1420, a fifth connecting section 1422, and a fourth film forming section 1424.

The second depositing section 1406 includes a second pretreating section 1426, a sixth connecting section 1428, a sixth film forming section 1430, a seventh connecting section 1432, a seventh film forming section 1434, an eighth connecting section 1436, and an eighth film forming section 1438.

The first pretreating section 1412 pretreats first substrates having a first film.

The third connecting section 1414 connects the first pretreating section 1412 to the second film forming section 1416, and transfers the pretreated first substrates to the first buffer cassette 1442 or the second film forming section 1416 by using a transfer means.

For example, in case that the process velocity of the first pretreating section 1412 is faster than that of the second film forming section 1416, the third connecting section 1414 transfers a part of the pretreated first substrates to the first buffer cassette 1442, and transfers the other first substrates to the second film forming section 1416.

For another example, in case that the second film forming section 1416 is broken down, the third connecting section 1414 transfers the pretreated first substrates to the first buffer cassette 1442.

The second film forming section 1416 deposits a second film on each of the first films of the pretreated first substrates.

The fourth connecting section 1418 connects the second film forming section 1416 to the third film forming section 1420, and transfers the first substrates having the second film to the second buffer cassette 1446 or the third film forming section 1420.

For example, in case that the process velocity of the second film forming section 1416 is faster than that of the third film forming section 1420, the fourth connecting section 1418 transfers a part of the first substrates having the second film to the second buffer cassette 1446, and transfers the other first substrates to the third film forming section 1420.

For another example, in case that the third film forming section 1420 is broken down, the fourth connecting section 1418 transfers the first substrates having the second film to the second buffer cassette 1446.

The third film forming section 1420 deposits a third film on each of the second films of the first substrates.

The fifth connecting section 1422 connects the third film forming section 1420 to the fourth film forming section 1424, and transfers the first substrates having the third film to the third buffer cassette 1450 or the fourth film forming section 1424 by using a transfer means.

For example, in case that the process velocity of the third film forming section 1420 is faster than that of the fourth film forming section 1424, the fifth connecting section 1422 transfers a part of the first substrates having the third film to the third buffer cassette 1450, and transfers the other first substrates to the fourth film forming section 1424.

For another example, in case that the fourth film forming section 1424 is broken down, the fifth connecting section 1422 transfers the first substrates having the third films to the third buffer cassette 1450.

The fourth film forming section 1424 deposits a fourth film on each of the third films of the first substrates, thereby producing second substrates having a first luminescent device.

The first connecting section 1404 connects the fourth film forming section 1424 to the first sealing section 1402, and transfers the second substrates to the fourth buffer cassette 1454 or the first sealing section 1402 by using a transfer means.

For example, in case that the process velocity of the fourth film forming section 1424 is faster than that of the first sealing section 1402, the first connecting section 1404 transfers a part of the second substrates to the fourth buffer cassette 1454, and transfers the other second substrates to the first sealing section 1402.

For another example, in case that the first sealing section 1402 is broken down, the first connecting section 1404 transfers the second substrates to the fourth buffer cassette 1454.

The first sealing section 1402 seals the transferred second substrates.

The second pretreating section 1426 pretreats third substrates having a fifth film. Here, the fifth film is substantially identical to the first film.

The sixth connecting section 1428 connects the second pretreating section 1426 to the sixth film forming section 1430, and transfers the pretreated third substrates to the first buffer cassette 1442 or the sixth film forming section 1430 by using a transfer means.

For example, in case that the process velocity of the second pretreating section 1426 is faster than that of the sixth film forming section 1430, the sixth connecting section 1428 transfers a part of the pretreated third substrates to the first buffer cassette 1442, and transfers the other third substrates to the sixth film forming section 1430.

For another example, in case that the sixth film forming section 1430 is broken down, the sixth connecting section 1428 transfers the pretreated third substrates to the first buffer cassette 1442.

The first buffer cassette 1442 stores the pretreated first substrates or third substrates, and transfers the stored substrates to the second film forming section 1416 or the sixth film forming section 1430.

The sixth film forming section 1430 deposits a sixth film on each of the fifth films of the pretreated third substrates. Here, the sixth film is substantially identical to the second film.

The seventh connecting section 1432 connects the sixth film forming section 1430 to the seventh film forming section 1434, and transfers the third substrates having the sixth film to the second buffer cassette 1446 or the seventh film forming section 1434 by using a transfer means.

For example, in case that the process velocity of the sixth film forming section 1430 is faster than that of the seventh film forming section 1434, the seventh connecting section 1432 transfers a part of the third substrates having the sixth film to the second buffer cassette 1446, and transfers the other third substrates to the seventh film forming section 1434.

For another example, in case that the seventh film forming section 1434 is broken down, the seventh connecting section 1432 transfers the third substrates having the sixth film to the second buffer cassette 1446.

The second buffer cassette 1446 stores the first substrates having the second film or the third substrates having the sixth film, and transfers the stored first or third substrates to the third film forming section 1420 or the seventh film forming section 1434.

The seventh film forming section 1434 deposits a seventh film on each of the sixth films of the third substrates. Here, the seventh film is substantially identical to the third film.

The eighth connecting section 1436 connects the seventh film forming section 1434 to the eighth film forming section 1438, and transfers the third substrates having the seventh film to the third buffer cassette 1450 or the eighth film forming section 1438 by using a transfer means.

For example, in case that the process velocity of the seventh film forming section 1434 is faster than that of the eighth film forming section 1438, the eighth connecting section 1436 transfers a part of the third substrates having the seventh film to the third buffer cassette 1450, and transfers the other third substrates to the eighth film forming section 1438.

For another example, in case that the eighth film forming section 1438 is broken down, the eighth connecting section 1436 transfers the third substrates having the seventh film to the third buffer cassette 1450.

The third buffer cassette 1450 stores the first substrates having the third film or the third substrates having the seventh film, and transfers the stored the first or third substrates to the fourth film forming section 1424 or the eighth film forming section 1438.

The eighth film forming section 1438 deposits an eighth film on each of the seventh films of the third substrates, thereby producing fourth substrates having a second luminescent device.

In one embodiment, the eighth film is substantially identical to the fourth film.

In addition, the second luminescent device is substantially identical to the first luminescent device.

The second connecting section 1410 connects the eighth film forming section 1438 to the second sealing section 1408, and transfers the fourth substrates to the fourth buffer cassette 1454 or the second sealing section 1408 by using a transfer means.

For example, in case that the process velocity of the eighth film forming section 1438 is faster than that of the second sealing section 1408, the second connecting section 1410 transfers a part of the fourth substrates to the fourth buffer cassette 1454, and transfers the other fourth substrates to the second sealing section 1408.

For another example, in case that the second sealing section 1408 is broken down, the second connecting section 1410 transfers the fourth substrates to the fourth buffer cassette 1454.

The second sealing section 1408 seals the fourth substrates.

In brief, the apparatus of the present invention further includes the buffer cassettes 1442, 1446, 1450 and 1454 compared with the conventional apparatus. Therefore, in case that a part of the depositing sections 1400 and 1406 is broken down, the apparatus of the present invention drives the other sections by using the buffer cassettes 1442, 1446, 1450 and 1454. As a result, the apparatus of the present invention may enhance the manufacture yield of the luminescent device.

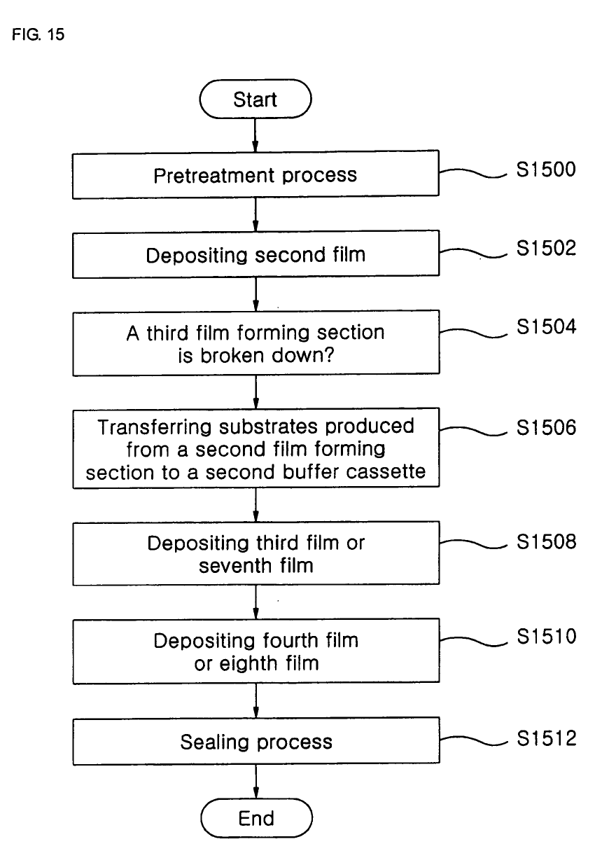

FIG. 15 is a flowchart illustrating process of manufacturing the luminescent device according to one embodiment of the present invention in case that a part of the film forming sections is broken down.

In FIG. 15, in step S1500, the first pretreating section 1316 pretreats the first substrates.

In step S1502, the second film forming section 1322 deposits the second film on each of the first films of the pretreated first substrates.

In step S1504, the third film forming section 1328 is broken down.

In step S1506, the first substrates passing through the second film forming section 1322 are transferred to the fourth buffer cassette 1326, and then stored therein.

In step S1508, in case that the third film forming section 1328 is repaired, the third films are deposited on the second films of the stored first substrates.

Otherwise, the seventh films are deposited on the second films of the stored first substrates.

In step S1510, the fourth film forming section 1334 deposits the fourth film on each of the third films of the first substrates, thereby producing the second substrates.

The eighth film forming section 1354 deposits the eighth film on the seventh films of the first substrates, thereby producing the fourth substrates.

In step S1512, the first sealing section 1302 seals the second substrates.

The second sealing section 1310 seals the fourth substrates.

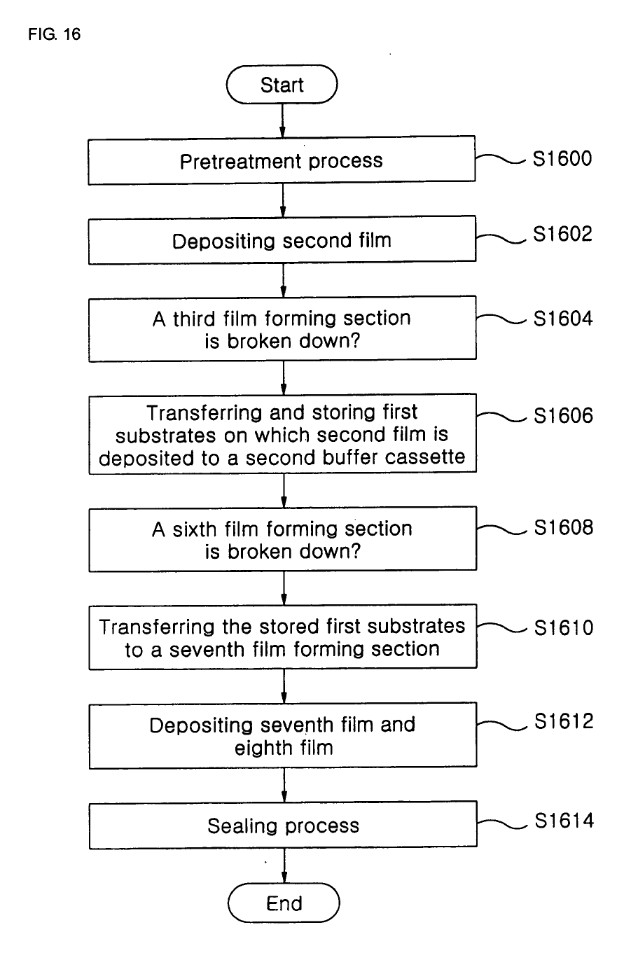

FIG. 16 is a flowchart illustrating process of manufacturing the luminescent device according to another embodiment of the present invention in case that a part of the film forming sections is broken down.

In FIG. 16, in step S1600, the first pretreating section 1412 pretreats the first substrates.

In step S1602, the second film forming section 1416 deposits the second film on each of the first films of the first substrates.

In step S1604, the third film forming section 1420 is broken down.

In step S1606, the first substrates having the second film are transferred to the second buffer cassette 1446, and then stored therein.

In step S1608, the sixth forming section 1430 is broken down.

In step S1610, the first substrates stored in the second buffer cassette 1446 are transferred to the seventh film forming section 1434.

In step S1612, the seventh and eighth film forming sections 1434 and 1438 deposit the seventh film and the eighth film on each of the second films of the first substrates, thereby producing the fourth substrates.

In step S1614, the second sealing section 1408 seals the fourth substrates.

From the preferred embodiments for the present invention, it is noted that modifications and variations can be made by a person skilled in the art in light of the above teachings. Therefore, it should be understood that changes may be made for a particular embodiment of the present invention within the scope and the spirit of the present invention outlined by the appended claims.

1. An apparatus of manufacturing a luminescent device comprising:
a depositing section for depositing a film on each of substrates;
a sealing section for receiving the deposited substrates from the depositing section, and sealing the received substrates; and
a buffer cassette for storing the substrates transferred from the depositing section, located between the depositing section and the sealing section.

2. The apparatus of claim 1, further including:
a first transfer means for transferring the deposited substrates from the depositing section to the sealing section;
a second transfer means for transferring the deposited substrates from the depositing section to the buffer cassette; and
a third transfer means for transferring the substrates stored in the buffer cassette to the sealing section.

3. The apparatus of claim 2, further including:
a controlling section for controlling operation of each of the transfer means to determine transfer route of the substrates.

4. The apparatus of claim 1, further including:
a connecting section for connecting the depositing section to the sealing section,
wherein the buffer cassette is combined with the connecting section.

5. An apparatus of manufacturing a luminescent device having a plurality of film forming sections for depositing a film on each of substrates and a sealing section for sealing the deposited substrates comprising:
at least one buffer cassette for storing the deposited substrates, located between the film forming sections.

6. The apparatus of claim 5, further including:
a first transfer means for transferring the deposited substrates between the film forming sections;
a second transfer means for transferring the deposited substrates from one of the film forming sections to the buffer cassette corresponding to the film forming section; and
a third transfer means for transferring the substrates stored in one of the buffer cassettes to the film forming section corresponding to the buffer casette.

7. The apparatus of claim 6, further including:
a controlling section for controlling operation of each of the transfer means to determine transfer route of the substrates.

8. An apparatus of manufacturing a luminescent device comprising:
a plurality of depositing sections for depositing a film on each of substrates;
at least one buffer cassette for receiving a part of the deposited substrates from the depositing sections, and storing the received substrates; and
at least one sealing section for sealing the deposited substrates.

9. The apparatus of claim 8, further including:
a first transfer means for transferring the deposited substrates from the depositing sections to the sealing section;
a second transfer means for transferring the deposited substrates from one of the depositing sections to the buffer cassette corresponding to the depositing section; and
a third transfer means for transferring the substrates stored in the buffer cassette to the sealing section.

10. The apparatus of claim 9, further including:
a controlling section for controlling operation of each of transfer means to determine transfer route of the substrates.

11. The apparatus of claim 8, further including:
a plurality of first connecting sections for connecting the depositing sections;
a second connecting section for connecting one of the depositing sections to the sealing section; and
a plurality of transfer means for transferring the deposited substrates between the connecting sections,
wherein the buffer cassettes are combined with the connecting sections.

12. An apparatus for manufacturing a luminescent device having a plurality of depositing sections including film forming sections for depositing films on substrates and a plurality of sealing sections for sealing the deposited substrates comprising:
at least one buffer cassette for storing the deposited substrates, located between the film forming sections.

13. The apparatus of claim 12, further including:
a plurality of first transfer means for transferring the deposited substrates between the film forming sections;
a plurality of second transfer means for transferring the deposited substrates from one of the film forming sections to the buffer cassette corresponding to the film forming section; and
a plurality of third transfer means for transferring the substrates stored in the buffer cassette to the film forming section corresponding to the buffer cassette.

14. The apparatus of claim 13, further including:
a controlling section for controlling operation of the transfer means to determine transfer route of the deposited substrates.

15. The apparatus of claim 12, further including:
a plurality of first connecting sections for connecting the film forming sections,
wherein first buffer cassettes of the buffer cassettes are combined with the first connecting sections.

16. The apparatus of claim 15, further including:
a plurality of second connecting sections for connecting the first connecting sections,
wherein second buffer cassettes of the buffer cassettes are combined with first connecting sections.
